(19) United States
(12) Patent Application Publication
(10) Pub. No.: US 2026/0282612 A1
(43) Pub. Date: Sep. 17, 2026

(54) SEMICONDUCTOR CHIP

(71) Applicant: ams-OSRAM International GmbH, Regensburg (DE)

(72) Inventors: Suraj NASKAR, Regensburg (DE); Fabian KOPP, Tanjung Tokong (MY); Anjan MUKHERJEE, Regensburg (DE)

(21) Appl. No.: 19/480,036

(22) PCT Filed: Apr. 24, 2024
(86) PCT No.: PCT/EP2024/061191

§ 371 Date: Oct. 30, 2025

(30) Foreign Application Priority Data
May 4, 2023 (DE) 10 2023 111 621.5

(51) Int. Cl. H10H 20/831

(52) U.S. Cl. CPC H10H 20/831

(57) ABSTRACT

A semiconductor chip including a semiconductor body with a first semiconductor layer of a first conductivity type, a second semiconductor layer of a second conductivity type different from the first conductivity type, and an active region configured to emit radiation, the active region being arranged between the first semiconductor layer and the second semiconductor layer, wherein: the first semiconductor layer is electrically connected to a first contact structure comprising at least one first contact finger; the at least one first contact finger includes a contact layer and a current distribution layer; the contact layer is arranged on the first semiconductor layer; a dielectric mirror is arranged in regions between the contact layer and the current distribution layer; the dielectric mirror includes at least one opening; and the current distribution layer extends through the at least one opening and directly adjoins the contact layer.

### CROSS-REFERENCE TO RELATED APPLICATIONS

This application is a national phase of International Application No. PCT/EP2024/061191 filed on Apr. 24, 2024, which claims priority to German patent application DE 10 2023 111 621.5, which was filed on May 4, 2023, the entire contents of both of which are incorporated herein by reference.

### FIELD OF THE INVENTION

The present application relates to a semiconductor chip.

### BACKGROUND

In semiconductor chips such as light emitting diodes, a comparably low lateral conductivity within semiconductor layers may cause an inhomogeneous charge carrier injection resulting in an inhomogeneous emission of radiation. Furthermore, metallic current spreader structures formed on the semiconductor chip may cause a significant absorption of the emitted radiation, thereby further decreasing the light extraction efficiency.

### SUMMARY

An object to be solved is to provide a semiconductor chip that exhibits an improved carrier injection efficiency and provides homogeneous radiation output.

This object is obtained inter alia by a semiconductor chip having the features of claim 1. Further expediencies and configurations are subject of the dependent claims.

A semiconductor chip comprising a semiconductor body is specified.

According to at least one embodiment of the semiconductor chip the semiconductor body comprises a first semiconductor layer of a first conductivity type, a second semiconductor layer of a second conductivity type different from the first conductivity type and an active region configured to emit radiation. For example, the first semiconductor layer is n-type and the second semiconductor layer is p-type or vice versa. The active region is arranged between the first Semiconductor layer and the second semiconductor layer.

The first semiconductor layer and/or the second semiconductor layer and/or the active region may be a single layer or comprise a plurality of sublayers. For example, the active region is configured to emit radiation in the ultraviolet spectral range. Alternatively, or in addition, the active region may be configured to emit radiation in the visible or infrared spectral range.

According to at least one embodiment of the semiconductor chip, the first semiconductor layer is electrically connected to a first contact structure comprising at least one first contact finger. For example, the first contact structure comprises a first contact pad configured for external electrical connection of the semiconductor chip.

According to at least one embodiment of the semiconductor chip, the at least one first contact finger comprises a contact layer. For example, the contact layer is arranged on the first semiconductor layer, in particular in direct contact to the first semiconductor layer. For example, the contact layer is that layer of the first contact structure which is arranged closest to the first semiconductor layer.

According to at least one embodiment of the semiconductor chip, the at least one first contact finger comprises a current distribution layer. The current distribution layer may comprise one or more partial layers. For example, the current distribution layer is at least in regions arranged on a side of the contact layer that faces away from the first semiconductor layer. In other words, the contact layer is arranged at least in regions between the current distribution layer and the first semiconductor layer. For example, the current distribution layer does not directly adjoin the first semiconductor layer at any position of the semiconductor chip.

According to at least one embodiment of the semiconductor chip, the semiconductor chip comprises a dielectric mirror. For example, the dielectric mirror is formed as a distributed Bragg reflector (DBR) comprising an alternating sequence of low refractive index and high reflective index dielectric layers. In particular, the dielectric mirror is configured to reflect the radiation emitted by the active region during operation of the semiconductor chip. For example, the reflectivity is at least 80% or at least 90% or at least 95% for a wavelength of maximum intensity of the radiation emitted by the active region.

According to at least one embodiment of the semiconductor chip, the dielectric mirror comprises at least one opening. In particular the at least one opening extends completely through the dielectric mirror in a vertical direction.

In the context of the present application, the vertical direction is a direction that extends perpendicularly with respect to the active region.

According to at least one embodiment of the semiconductor chip, the current distribution layer extends through the at least one opening and directly adjoins the contact layer. Thus, the current distribution layer directly adjoins the contact layer within the at least one opening. Laterally beside the at least one opening, the dielectric mirror is arranged at least in regions between the contact layer and the current distribution layer. Consequently, the current injection into the first semiconductor layer predominantly occurs directly below the at least one opening.

In at least one embodiment of the semiconductor chip, the semiconductor chip comprises a semiconductor body with a first semiconductor layer of a first conductivity type, a second semiconductor layer of a second conductivity type different from the first conductivity type and an active region configured to emit radiation, wherein the active region is arranged between the first semiconductor layer and the second semiconductor layer. The first semiconductor layer is electrically connected to a first contact structure comprising at least one first contact finger. The at least one first contact finger comprises a contact layer and a current distribution layer, wherein the contact layer is arranged on the first semiconductor layer. A dielectric mirror is arranged in regions between the contact layer and the current distribution layer. The dielectric mirror comprises at least one opening and the current distribution layer extends through the at least one opening and directly adjoins the contact layer.

The current injection via the first contact structure into the first semiconductor layer can be controlled by an appropriate configuration of the at least one opening during the production of the semiconductor chip. In particular current crowding along the edges of the first contact finger can be avoided or at least reduced. Consequently, a more homogeneous emission of radiation from the semiconductor chip can be obtained.

Furthermore, the dielectric mirror may reflect radiation emitted towards the first contact structure with a high efficiency so that the light extraction can be further improved.

In this context the term “light” is not restricted to visible light, but also includes radiation in the ultraviolet and the infrared spectral range.

According to at least one embodiment of the semiconductor chip, the contact layer has a thickness of at most 20 nm or at most 10 nm at most 5 nm.

Compared to a thicker contact layer, a higher transparency can be obtained for the radiation emitted by the active region. Consequently, absorption losses within the contact layer may be reduced. The radiation transmitted through the contact layer may be reflected at the dielectric mirror.

Furthermore, the lateral current spreading within the contact layer is intentionally reduced by means of the comparably low thickness of the contact layer. Thus, charge carrier injection into the first semiconductor layer occurs almost completely or at least predominantly directly below the at least one opening. In other words, lateral current spreading within the contact layer is insignificant.

For example, the contact layer comprises a metal such as rhodium, palladium, nickel, chromium, titanium, gold, silver or platinum. For example, the contact layer comprising a metal or consisting of a metal has a thickness of at least 0.5 nm.

Alternatively, the contact layer may comprise graphene. For example, the contact layer comprises a single monolayer or a plurality of stacked monolayers of graphene, for example at most 10 monolayers.

Using graphene, a particularly high transparency can be obtained, for example in the UV-C spectral range.

According to at least one embodiment of the semiconductor chip, a plurality of openings is arranged within the at least one first contact finger in a top view of the semiconductor chip. For example, at least one of the openings has a circular, elliptical or polygonal, for example rectangular or hexagonal shape. For example, a ratio between a longitudinal extent and a transverse extent of the at least one opening is between 1:1 and 20:1 inclusive.

For example, two or more openings are arranged laterally beside one another along an axis of the first contact finger. In a top view of the semiconductor chip, the axis of the first contact finger may be straight, for example with one or more kinks or bends, or it may be curved at least in regions.

For example, the at least one opening is spaced apart from an edge of the first contact finger. Thus, the current injection spaced apart from the edge of the first contact finger is increased.

According to at least one embodiment of the semiconductor chip, two of the plurality of openings differ from one another with respect to a transverse extent perpendicular to an axis of the at least one first contact finger by at least 50%. Using different sizes for the openings, the local current injection below the at least one first contact finger can be varied such that a more homogeneous emission of light is obtained.

According to at least one embodiment of the semiconductor chip, a transverse extent of the openings perpendicular to an axis of the at least one first contact finger decreases at least along one direction within the at least one first contact finger. For example, the at least one direction extends in parallel to the axis of the first contact finger. For example, the opening having the largest transverse extent perpendicular to the axis of the first contact finger is located at or near the centre of the first contact finger and the lateral extent of the further openings decreases in two opposite directions, starting from the centre of the at least one first contact finger.

Alternatively, the at least one direction extends perpendicular to the axis of the first contact finger. For example, openings arranged closer to the axis of the first contact finger have a larger transverse extent than one or more openings arranged further away from the axis of the first contact finger. Consequently, current injection along the axis of the first contact finger is increased compared to the injection along the edges of the first contact finger.

According to at least one embodiment of the semiconductor chip, a longitudinal extent of the at least one opening in a direction parallel to an axis of the at least one first contact finger is at least 50% or at least 80% of a length of the at least one first contact finger. For example, the at least one opening is configured as a line-shaped opening that extends almost over the entire length of the first contact finger.

According to at least one embodiment of the semiconductor chip, the at least one opening comprises a main region and at least one side region. For example, the main region extends along an axis of the at least one first contact finger and one or a plurality of side regions extend from the main region in a direction away from the axis. For example, the side regions are arranged on both sides of the main region. For example, the at least one opening has a shape resembling a caterpillar.

In this case, a single opening having the described specific shape ensures significant charge carrier injection along the axis of the first contact finger, thereby reducing current crowding effects along the edges of the first contact finger.

The semiconductor body, in particular the active region may comprise a III-V compound semiconductor material.

III-V compound semiconductor materials are suitable for radiation generation in the ultraviolet (AlₓIn_{y}Ga_{1-x-y}N) over the visible (AlₓIn_{y}Ga_{1-x-y}N, especially for blue to green radiation, or AlₓIn_{y}Ga_{1-x-y}P, in particular for yellow to red radiation) to the infrared (AlₓIn_{y}Ga_{1-x-y}As) spectral range. The following applies in each case: 0≤x≤1, 0≤y≤1 and x+y≤1, in particular with x≠1, y≠1, x≠0 and/or y≠0. With III-V compound semiconductor materials, in particular from the above-mentioned material systems, high internal quantum efficiencies can be achieved.

According to at least one embodiment of the semiconductor chip, the active region is configured to emit radiation in the ultraviolet spectral range. For example, a wavelength of maximum intensity is at most 400 nm. For example, the active region, or at least a layer thereof, is based on nitride compound semiconductor material.

“Based on nitride compound semiconductor material” means in the present context that the semiconductor layer sequence or at least a part thereof, for example at least the active region and/or the growth substrate, comprises a nitride compound semiconductor material, preferably AlₓIn_{y}Ga_{1-x-y}N where 0≤x≤1, 0≤y≤1 and x+y≤1. This material does not necessarily have to have a mathematically exact composition according to the above formula. Rather, it may comprise, for example one or more dopants and additional components. For the sake of simplicity, the above formula only contains the essential components of the crystal lattice (Al, Ga, In, N), even if these may in part be replaced and/or supplemented by small amounts of other substances.

According to at least one embodiment of the semiconductor chip, a material of the first semiconductor layer directly adjoining the contact layer comprises AlₓGa₁₋ₓN. For example, the aluminum content x is at least 0.02 or at least 0.05 or at least 0.1 or at least 0.2. Compared to GaN, this material has a higher transparency for radiation in the ultraviolet spectral range (wavelength from 100 nm to 400 nm inclusive), for instance in the UV-C spectral range (wavelength from 100 nm to 280 nm inclusive).

The semiconductor chip emitting in the ultraviolet spectral range may be used for surface disinfection or water purification applications, for example. For example, the radiation may act as a germicide killer.

According to at least one embodiment of the semiconductor chip, the second semiconductor layer is electrically connected to a second contact structure. For example, the second contact structure extends through at least one via of the semiconductor body through the first semiconductor layer and the active region into the second semiconductor layer.

According to at least one embodiment of the semiconductor chip, the semiconductor chip comprises contact pads for external electrical contacting of the semiconductor chip, wherein the contact pads are arranged on a side of the semiconductor body that is remote from a radiation exit side of the semiconductor chip. Thus, the radiation exit side of the semiconductor chip is free of contact structures required for external electric contacting of the semiconductor chip.

According to at least one embodiment of the semiconductor chip, the semiconductor chip comprises a substrate wherein the substrate in particular forms the radiation exit side. For example, the substrate is a growth substrate for an epitaxial deposition of the semiconductor layers of the semiconductor body. For example, the substrate comprises sapphire or silicon carbide. Semiconductor chips having this type of contact configuration with respect to the substrate are also referred to as flip chips.

Features described above in connection with at least one embodiment of the semiconductor chip can be combined with other features described in connection with at least one embodiment of the semiconductor chip unless they are contradictory. Further features and expediencies will become apparent from the subsequent description of the exemplary embodiments in connection with the figures.

In the exemplary embodiments and figures similar or similarly acting constituent parts are provided with the same reference signs. Generally, only the differences with respect to the individual embodiments are described. Unless specified otherwise, the description of a part or aspect in one embodiment applies to a corresponding part or aspect in another embodiment as well.

### BRIEF DESCRIPTION OF THE FIGURES

In the figures:

FIG. 1A shows an exemplary embodiment of a semiconductor chip in a cross-sectional view;

FIG. 1B shows an exemplary embodiment of a semiconductor chip in a top view;

FIGS. 2A, 2B, 2C, 2D and 2E each show an exemplary embodiment of a first contact finger in a top view; and

FIG. 3 shows an exemplary embodiment of a semiconductor chip in a top view.

### DETAILED DESCRIPTION OF THE FIGURES

The figures are schematic illustrations. Thus, the elements illustrated in the figures and their size relationships among one another are not necessarily true to scale. Rather, individual elements or layer thicknesses may be represented with an exaggerated size for the sake of better representability and/or for the sake of better understanding.

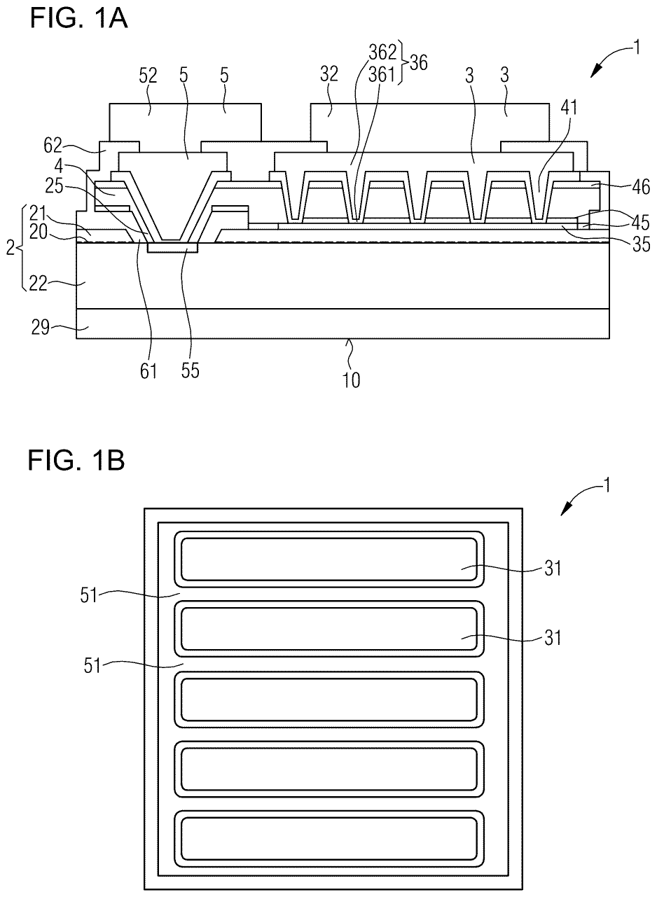

In the exemplary embodiment of FIG. 1A a semiconductor chip 1 comprises a semiconductor body 2 comprising an active region 20 arranged between a first semiconductor layer of a first conductivity type 21 and a second semiconductor layer 22 of a second conductivity type. For example, the first semiconductor layer is p-type and the second layer 22 is n-type or vice versa.

The first semiconductor layer 21 is electrically connected to a first contact structure 3 comprising at least one first contact finger 31.

An exemplary embodiment of the arrangement of the first contact fingers 31 and second contact fingers 51 of a second contact structure 5 is illustrated in FIG. 1B. The first contact fingers 31 of the first contact structure 3 are electrically connected to one another and are externally electrically contactable via a first contact pad 32. Likewise, the second contact fingers 51 of the second contact structure 5 are electrically contactable via a second contact pad 52.

The first contact pad 32 and the second contact pad 52 are arranged on a side of the semiconductor body 2 facing away from a radiation exit side 10 of the semiconductor chip 1. In the exemplary embodiment shown, the radiation exit side is formed by a substrate 29. For example, the substrate is a growth substrate for epitaxial growth of the semiconductor layers of the semiconductor body 2. Thus, the semiconductor chip 1 represents a flip chip.

The at least one first contact finger 31 comprises a contact layer 35 and a current distribution layer 36. In the exemplary embodiment shown the current distribution layer 36 comprises a first partial layer 361 and a second partial layer 362. However, the current distribution layer may also comprise only one layer or more than two partial layers.

The contact layer 35 is arranged on the first semiconductor layer 21 and directly adjoins the first semiconductor layer 21. For example the contact layer 35 is a thin metal layer having a thickness of at most 20 nm or at most 10 nm or at most 5 nm. Alternatively, the contact layer may comprise or consist of one or more monolayers of graphene.

A dielectric mirror 4 is arranged in regions between the contact layer 35 and the current distribution layer 36. The dielectric mirror 4 comprises at least one opening 41 wherein the current distribution layer 36 extends through the at least one opening 41 and directly adjoins the contact layer 35. Radiation produced in the active region 20 by recombination of electron hole pairs and emitted in a direction away from the radiation exit side 10 may pass through the comparably thin contact layer 35 and be reflected at the dielectric mirror 4 with high efficiency. This helps to improve the light extraction efficiency.

For example, the dielectric mirror 4 is configured as a distributed Bragg reflector comprising an alternating stack of low refractive index layers, for example comprising SiO₂, MgF₂ or AlF₃ and high refractive index layers, for example comprising Y₂O₃-doped HfO₂ (YDH) or HfO₂.

For example, the reflectivity of the dielectric mirror 4 for the radiation produced in the active region 20 is at least 80% or at least 90% or at least 95%.

The contact layer 35 has a comparably low conductivity in transverse direction, i.e. in a direction that extends in parallel to the active region 20 of the semiconductor chip 1. Consequently, the injection of charge carriers into the first semiconductor layer 21 predominantly occurs directly below the at least one opening 41. Thus, an appropriate choice of the configuration of the at least one opening 41 allows the carrier injection to be controlled from the first contact finger 31 into the first semiconductor layer 21. In particular, the generation of radiation below the first contact fingers 31 can be increased. In conventional semiconductor chips using contact fingers, in contrast, recombination of charge carriers predominantly takes place along the edges of the first contact fingers 31 due to current crowding effects. Consequently, the semiconductor chip 1 takes advantage of the comparably high transmission as well as the comparably low transverse electrical conductivity of a thin contact layer directly adjoining the first semiconductor layer 21.

By the elimination of current crowding effects and introducing a homogeneous current distribution all over the first contact fingers 31, better light outcoupling and less local heating of the first contact fingers 31 can be obtained. This results in a higher light extraction efficiency and a better thermal stability of the semiconductor chip 1.

The described configuration of the semiconductor chip 1 can be used for the generation of radiation in the visible ultraviolet or infrared spectral range. For example, radiation in the ultraviolet spectral range, for example in the UV-C spectral range can be produced with high efficiency as a low light absorption by the contact layer 35 and a high reflectivity on account of the dielectric mirror 4 can be obtained, for example compared to a semiconductor chip using a contact layer of a transparent conductive oxide such as ITO.

For example, the material of the first semiconductor layer 21 may be formed from AlGaN, in particular in combination with an active region 20 based on nitride compound semiconductor material. Compared to GaN used in conventional devices, AlGaN may have a significantly lower absorption in the ultraviolet spectral range.

The semiconductor chip 1 according to FIG. 1A further includes a first insulation layer 61 that electrically insulates the first semiconductor layer 21 and the active region 20 from the second contact structure 5. In particular, the first insulation layer 61 covers sides faces of one or more vias 25 extending through the first semiconductor layer and the active region 20 into the second semiconductor layer 22. The second semiconductor layer 22 is electrically contacted via a further contact layer 55 arranged in the via(s) 25.

A second insulating layer 62 electrically insulates the first contact structure 3 from the second contact structure 5. The first and/or second insulating layer may comprise an oxide or a nitride, for instance.

The semiconductor chip 1 further comprises a protection layer 45. The protection layer 45 may be used to protect the contact layer 35 during the production of the semiconductor chip and may in particular serve as an etch stop layer when the at least one opening 41 is produced through the dielectric mirror 4.

On a side of the dielectric mirror 4 facing away from the semiconductor body 2 an adhesion promotion layer 46 is arranged. The adhesion promotion layer 46 may improve the adhesion of a resist used for the structuring processes during production, for example.

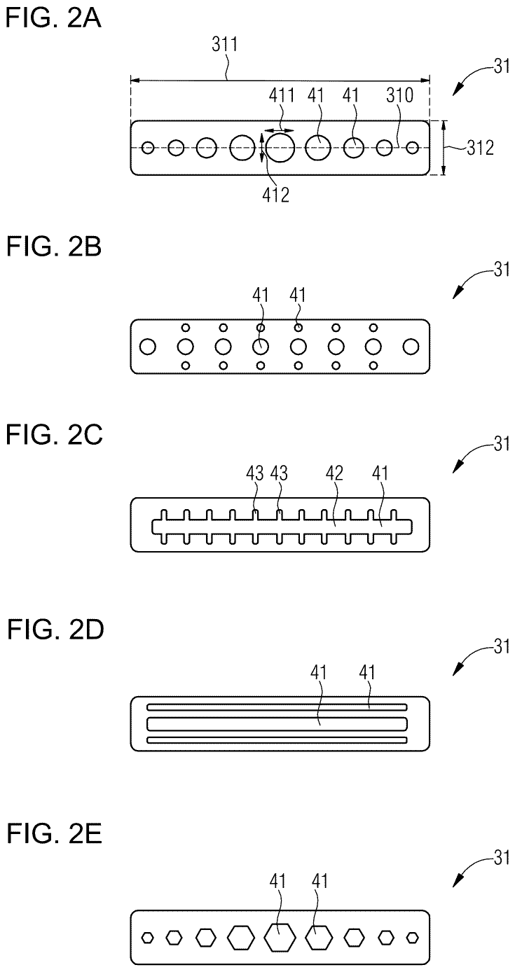

FIGS. 2A to 2E illustrate different exemplary embodiments of configurations of the at least one opening 41 within the first contact finger 31.

As illustrated in FIG. 2A, the first contact finger 31 extends along an axis 310. Along the axis the first contact finger 31 has a longitudinal extent 311. In a direction extending perpendicular to the axis, the first contact finger 31 has a transverse extent 312. For example, the ratio between the longitudinal extent 311 and the transverse extent 312 of the first contact finger 31 is in a range from 1:1 to 20:1 inclusive.

In the exemplary embodiment shown, the axis 310 of the first contact finger 31 is straight. However, the axis 310 may also comprise bends or kinks and/or be curved at least in regions.

The at least one opening 41 likewise has a longitudinal extent 411 along the axis 310 of the first contact finger 31 and a transverse extent 412 in a direction perpendicular to the axis 310.

In the exemplary embodiment of FIG. 2A, the openings 41 differ from one another with respect to the longitudinal extent 411 and the transverse extent 412. For example, the openings 41 have a circular shape, so that the longitudinal extent 411 equals the transverse extent 412. However, other shapes may also apply, for example elliptical shapes or rectangular shapes or hexagonal shapes as illustrated in FIG. 2E.

For example the ratio between the transverse extent of the largest opening 41 to the transverse extent of the smallest opening 41 within one first contact finger may vary from 1:1 to 10:1 inclusive.

Starting from the center of the first contact finger 31, the diameter of the openings 41 decreases with increasing distance from the center of the first contact finger 31. For example, the opening 41 at the center of the first contact finger 31 has a diameter of 100 μm whereas the smallest opening 41 located closest to the edge of the first contact finger 31 has a diameter of 20 μm.

In the exemplary embodiments of FIG. 2A and FIG. 2E, the openings 41 are arranged along the axis 310 of the first contact finger 31. Consequently, the injection of charge carriers directly below the axis 310 of the first contact finger 31 is increased so that a more homogeneous light generation is obtained.

In the exemplary embodiment of FIG. 2B the first contact finger 31 comprises openings 41 extending along the axis 310 of the first contact finger 31 and further openings 41 spaced apart from the axis 310. The openings 41 arranged further away from the axis have a smaller transverse extent 412 than the openings 41 overlapping with the axis 310. This configuration likewise exhibits increased injection of charge carriers directly below the axis 310 of the first contact finger 31 resulting in a more homogeneous light generation in the active region 20.

In the exemplary embodiment of FIG. 2C, the first contact finger 31 comprises exactly one opening 41 wherein the opening 41 comprises a main region 42 extending along the axis 310 and further comprises a plurality of side regions 43 extending away from the main region 42 in a direction perpendicular to the axis 310. A ratio of the longitudinal extent of the side regions 42 to the longitudinal extent of the main region 42 may be between 1:5 and 1:20 inclusive, for example. A ratio of the transverse extent of the side regions 43 with respect to the transverse extent of the main region 42 may be between 1:1 and 1:10 inclusive.

For example, the longitudinal extent 411 of the main region 42 is at least 50% or at least 80% of the longitudinal extent 311 of the first contact finger 31.

Unlike in the embodiment of FIG. 2C shown, one first contact finger 31 may be assigned to more than one opening 41 having a main region 42 and at least one side region 43.

In the exemplary embodiment of FIG. 2D, the first contact finger 31 comprises a plurality of line-shaped openings 41. The longitudinal extent 411 of the openings 41 is at least 50% or at least 80% of the longitudinal extent 311 of the first contact finger 31. The opening overlapping with the axis 310 of the first contact finger 31 has a larger transverse extent than the openings 41 spaced apart from the axis 310 in transverse direction. This configuration likewise increases the light generation directly below the axis of the first contact finger 31, resulting in a better homogeneity of light generation within the active region 20.

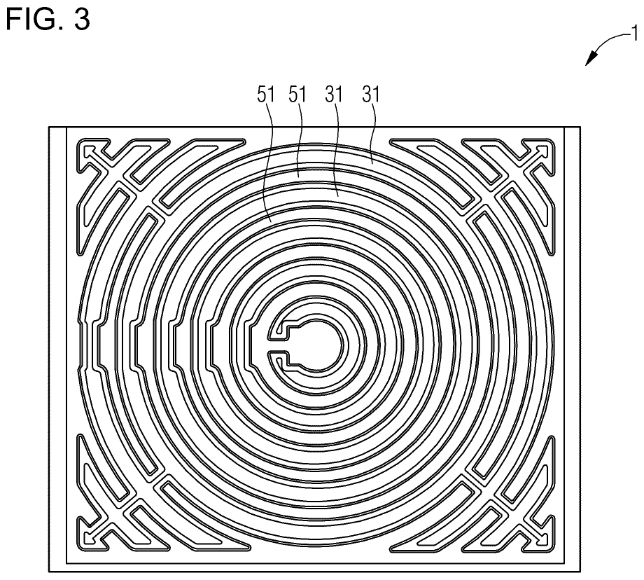

FIG. 3 illustrates a further exemplary embodiment of a semiconductor chip in a top view, wherein the first contact fingers 31 and the second contact fingers 51 are shown. In this exemplary embodiment the axes 310 of the contact fingers 31, 51 are not straight, but have a curved, for example, circular shape. Within such first contact fingers 31 the at least one opening 41 can be configured with respect to the axis 310 as described in connection with FIGS. 2A to 2E, for example.

The invention described herein is not restricted by the description given with reference to the exemplary embodiments. Rather, the invention encompasses any novel feature and any combination of features, including in particular any combination of features in the claims, even if this feature or this combination is not itself explicitly indicated in the claims or exemplary embodiments.

### REFERENCES

1 semiconductor chip
10 radiation exit side
2 semiconductor body
20 active region
21 first semiconductor layer
22 second semiconductor layer
25 via
29 substrate
3 first contact structure
31 first contact finger
310 axis
311 longitudinal extent
312 transverse extent
32 first contact pad
35 contact layer
36 current distribution layer
361 first partial layer
362 second partial layer
4 dielectric mirror
41 opening
411 longitudinal extent
412 transverse extent
42 main region
43 side region
45 projection layer
46 adhesion promoting layer
5 second contact structure
51 second contact finger
52 contact pad
55 further contact layer
61 first insulation layer
62 second insulation layer

1. A semiconductor chip comprising a semiconductor body with a first semiconductor layer of a first conductivity type, a second semiconductor layer of a second conductivity type different from the first conductivity type, and an active region configured to emit radiation, the active region being arranged between the first semiconductor layer and the second semiconductor layer, wherein:
the first semiconductor layer is electrically connected to a first contact structure comprising at least one first contact finger;
the at least one first contact finger comprises a contact layer and a current distribution layer;
the contact layer is arranged on the first semiconductor layer;
a dielectric mirror is arranged in regions between the contact layer and the current distribution layer;
the dielectric mirror comprises at least one opening; and
the current distribution layer extends through the at least one opening and directly adjoins the contact layer.

2. The semiconductor chip according to claim 1, wherein the contact layer has a thickness of at most 5 nm.

3. The semiconductor chip according to claim 1, wherein in a top view of the semiconductor chip a plurality of openings is arranged within the at least one first contact finger.

4. The semiconductor chip according to claim 3, wherein two of the plurality of openings differ from one another with respect to a transverse extent perpendicular to an axis of the at least one first contact finger by at least 50%.

5. The semiconductor chip according to claim 3, wherein a traverse extent of the openings perpendicular to an axis of the at least one first contact finger decreases at least along one direction within the at least one first contact finger.

6. The semiconductor chip according to claim 5, wherein the at least one direction extends in parallel to the axis of the at least one first contact finger.

7. The semiconductor chip according to claim 5, wherein the at least one direction extends perpendicular to the axis of the first contact finger.

8. The semiconductor chip according to claim 1,
wherein a longitudinal extent of the at least one opening in a direction parallel to an axis of the at least one first contact finger is at least 50% of a longitudinal extent of the at least one first contact finger.

9. The semiconductor chip according to claim 1,
wherein the at least one opening comprises a main region extending along an axis of the at least one first contact finger and wherein the at least one opening comprises a plurality of side regions extending from the main region in a direction away from the axis.

10. The semiconductor chip according to claim 1,
wherein the active region is configured to emit radiation in the ultraviolet spectral range.

11. The semiconductor chip according to claim 1,
wherein a material of the first semiconductor layer directly adjoining the contact layer comprises AlₓGa₁₋ₓN.

12. The semiconductor chip according to claim 1,
wherein the second semiconductor layer is electrically connected to a second contact structure.

13. The semiconductor chip according to claim 1,
wherein the semiconductor chip comprises contact pads for external electrical contacting of the semiconductor chip, the contact pads being arranged on a side of the semiconductor body that is remote from a radiation exit side of the semiconductor chip.

14. The semiconductor chip according to claim 13, wherein the semiconductor chip comprises a substrate, the substrate forming the radiation exit side.
